(19) United States
(12) Patent Application Publication
(10) Pub. No.: US 2010/0195082 A1
(43) Pub. Date: Aug. 5, 2010

(54) Device, System, And Method For Multidirectional Ultraviolet Lithography

(76) Inventors: Yong-Kyu Yoon, Amherst, NY (US); JungKwun Kim, North Tonawanda, NY (US); Mark G. Allen, Atlanta, GA (US)

Correspondence Address: HODGSON RUSS LLP;THE GUARANTY BUILDING, 140 PEARL STREET, SUITE 100, BUFFALO, NY, 14202-4040, US

(21) Appl. No.: 12/694,936

(22) Filed: Jan. 27, 2010

Related U.S. Application Data
(60) Provisional application No. 61/147,602, filed on Jan. 27, 2009.

(51) Int. Cl. G03B 27/58; G03F 7/20; B65D 85/00

(52) U.S. Cl. 355/72; 430/322; 206/525

(57) ABSTRACT

A system according to an embodiment of the present invention comprises a movable stage having a top surface. A photosensitive material may be deposited on the top surface and a mask may be placed on the photosensitive material. A vessel, having a top portion, one or more flexible sides, and a transparent base, is configured to be placed adjacent to the mask. The base is configured to be movable relative to the top portion of the vessel. In this way, the movable stage, photosensitive material, and mask may move in conjunction with the base of the vessel.

### CROSS-REFERENCE TO RELATED APPLICATION

This application claims the benefit of priority to U.S. provisional patent application Ser. No. 61/147,602, filed on Jan. 27, 2009, now pending, the disclosure of which is incorporated herein by reference.

This invention was made with government support under CAREER-ECCS 0748153 and CMMI 0826434 awarded by the National Science Foundation. The government has certain rights in the invention.

### BACKGROUND OF THE INVENTION

An inclined ultraviolet (“UV”) exposure scheme has previously been demonstrated to fabricate complex three dimensional (“3D”) microstructures such as vertical screen filters, mixers, horn, and nozzles. See Y. K. Yoon, J.-H. Park, and M. G. Allen, “Multidirectional UV lithography for complex 3-D MEMS Structures,” Journal of MEMS, vol. 15, no. 5. pp. 1121-1130, 2006, H. Sato, T. Kakinuma, J. S. Go, and S. Shoji, “Inchannel 3-D Micromesh Structures using Maskless Multi-Angle Exposures and their Microfilter Application,” Sensors and Actuators A, III (2004), pp. 87-92, M. Han, W. Lee, S.-K. Lee, and S. S. Lee, “Fabrication of 3D microstructures with inclined/rotated UV lithography,” Proceedings of IEEE Micro Electro Mechanical Systems, 2003, pp. 554-557, and Y. K. Yoon and M. G. Allen, “Proximity Mode Inclined UV Lithography,” Solid-State Sensor, Actuator, and Microsystems Workshop, Hilton Head Island, S.C., Jun. 4-8, 2006, pp. 98-99.

This process was further advanced using an automated multidirectional scheme, wherein a collimated UV source is incorporated with a movable stage equipped with two computer controlled motors and a microcontroller, for fabricating more complex 3D microstructures such as a vertical triangular slab, a quadruple triangular slab, a cardiac horn, screwed wind vane shapes. See J. K. Kim, M. G. Allen, Y. K. Yoon, “Automated dynamic mode multidirectional UV lithography for complex 3-D microstructures,” Proceedings of IEEE Micro Electro Mechanical Systems, Jan. 13-17, 2008, Tucson, Ariz., pp. 399-402. However, those previous methods have been performed in an air environment and thus are limited in the achievable flare or inclined angle of the fabricated structures due to the high refractive index difference between air and the photopatternable photoresist material (typically SU-8—having a refractive index of 1.69). The refractive index of air being unity (1), the maximum achievable incline angle of the fabricated structure is less than 35° as measured from vertical to the substrate surface.

A method to overcome the limit of the inclined the index matching approach using a liquid medium was previously demonstrated. See K. Y. Hung, H. T. Hu, F. G. Tseng, “A novel fabrication technology for smooth 3D inclined polymer microstructures and adjustable angles,” Proceedings of Solid State Sensors Actuators, Microsystems (Transducers '03), Boston, Mass., 2003, pp. 821-824. In this method, to overcome the refractive index difference between air and SU-8, glycerol, having a refractive index of 1.56, was used between the air and the photosensitive material. However, in this approach the static tilting stage and the sample substrate were submerged in glycerol. This increases the chances of contamination during the fabrication process. Additionally, complex mechanisms to provide movement of the stage during fabrication (“dynamic operation”) may be necessary.

Therefore there is a need for a method and/or device/system that overcomes the limit of the inclined angle for three dimensional microstructures fabricated using conventional dynamic mode multidirectional ultraviolet (UV) lithography, decreases the changes of contamination, and may be applied to dynamic operation.

### BRIEF SUMMARY OF THE INVENTION

The current disclosure provides a method and apparatus/system for dynamic mode multidirectional ultraviolet (UV) lithography that uses a liquid-state refractive index matching medium to overcome the limit of the inclined angle for three-dimensional (3D) microstructures that are fabricated using conventional dynamic mode multidirectional ultraviolet (UV) lithography. The proposed approach uses an isolated container for an index matching medium without direct contact between the index matching medium and the sample, reducing the chance of contamination, simplifying the fabrication process, and broadening the selection of an index matching medium. In addition, the liquid container is designed to allow in-situ adjustable refractive index matching performance during a dynamic mode operation. A refracted angle of 58.5° for an incident angle of 67.5° has been obtained for an SU-8 structure using glycerol as an index matching medium. UV lithography using water, solvent, acid, oil, and starch syrup as an index matching medium has been demonstrated. Various microstructures with large inclined or flare angles such as a chevron shape, an ellipsoidal horn, and a chained wind vane are successfully demonstrated with dynamic mode multidirectional UV lithography.

A system according to an embodiment of the present invention comprises a movable stage having a top surface. A photosensitive material may be deposited on the top surface and a mask may be placed on the photosensitive material. (Although the photosensitive material and mask are workpiece elements and do not necessarily form a part of the inventive system). A vessel, having a top portion, one or more flexible sides, and a transparent base, is configured to be placed adjacent to the mask. The base is configured to be movable relative to the top portion of the vessel. In this way, the movable stage, photosensitive material, and mask may move in conjunction with the base of the vessel.

The invention may be also be embodied as a vessel as further described herein, without a stage. The invention may also be embodied as a method for multidirectional ultraviolet lithography. In such a method, a movable stage, a photosensitive material, and a vessel are provided. An ultraviolet light source is used to pass ultraviolet light through the vessel to cause the photosensitive material to react. The photosensitive material may be exposed to the ultraviolet light for a predetermined period of time. The stage may be caused to move before and/or during the predetermined period of time.

### DESCRIPTION OF THE DRAWINGS

For a fuller understanding of the nature and objects of the invention, reference should be made to the following detailed description taken in conjunction with the accompanying drawings, in which:

FIG. 1A is a cross-section view of a system for multidirectional ultraviolet lithography according to an embodiment of the present invention;

FIG. 1B is a cross-section view of the system of FIG. 1A, wherein the stage and other components are moved relative to the top portion;

FIG. 2A is a schematic of system according to an embodiment of the invention, showing the vessel separate from the stage;

FIG. 2B is a schematic of the system of FIG. 2B showing the vessel in contact with a mask;

FIG. 2C is a schematic of the system shown in FIGS. 2A and 2B depicting the stage tilting and/or rotating;

FIG. 3 shows a fabricated SU-8 structure (tilted pillars made by refracted UV light) from an open window with a diameter of 25 μm and a thickness of 250 μm;

FIG. 4 is a graph show incident angle versus refracted angle for various liquid refractive index media;

FIG. 5A is a graphic depicting light refracted at interfaces due to different refractive indices of materials;

FIG. 5B shows an inclined and reflected pillar array with a refracted angle of 45 degrees from bottom exposure;

FIG. 6A shows an array of ellipsoidal horns fabricated using a dynamic mode operation, fabricated using a flare angle of 90 degrees;

FIG. 6B shows matching dynamic mode operation with glycerol as a matching medium shows a chained wind vane with a flare angle of 85 degrees compared to the isolated wind vane performed in an air environment with a flare angle of 45 degrees;

FIG. 7 shows exemplary structures capable of fabrication using a system and/or method according to the present invention;

FIGS. 8A-8D show examples of various structures capable of fabrication using a system and/or method according to the present invention, including a “chevron and shield” (8A and 8B) and an ellipsoidal horn (8C and 8D);

FIGS. 9A and 9B show structures fabricated using multidirectional UV lithography in an air environment (9a) compared to that of a glycerol environment using a system according to an embodiment of the present invention (9B);

FIG. 10 is graphical comparison of light refraction without and with an index matching medium; and

FIG. 11 is a method according to another embodiment of the present invention.

### DETAILED DESCRIPTION OF THE INVENTION

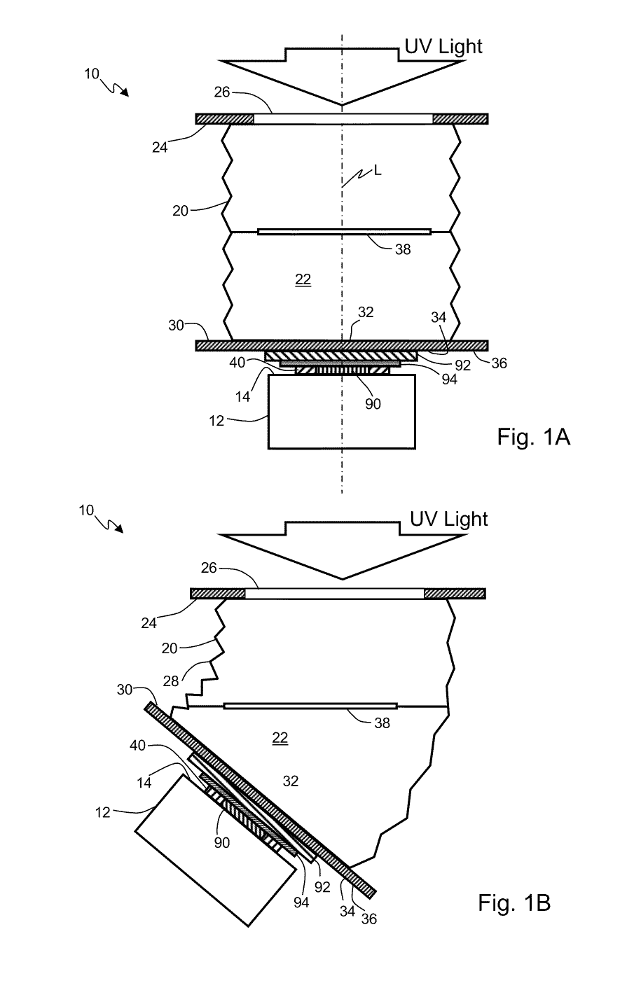

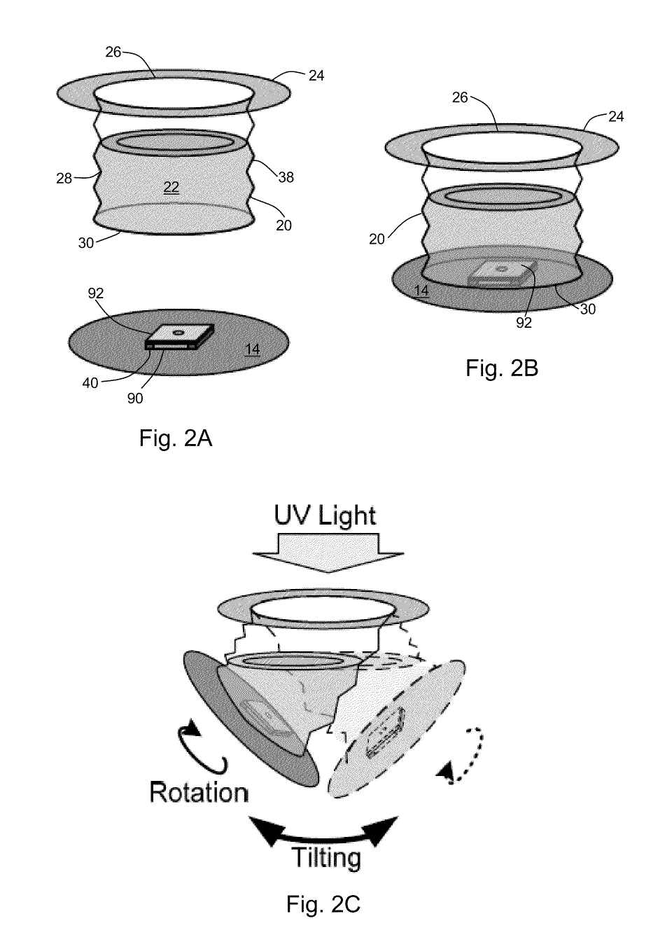

FIG. 1A depicts a system 10 for multidirectional ultraviolet lithography according to an embodiment of the present invention, which comprises a stage 12 having a top surface 14. The stage 12 is movable such that the stage 12 may tilt and/or rotate. The top surface 14 may receive a photosensitive material 90, such as, for example, SU-8. The photosensitive material 90 may be deposited on the top surface 14 as a film by, for example, allowing liquid photosensitive material to dry. Other methods of deposition are known to those skilled in the art.

A mask 92 may be placed on the photosensitive material 90. The mask 92 may have one or more portions transparent to ultraviolet light and one or more portions opaque to ultraviolet light. The opaque portion(s) may be formed by a chrome layer 94 deposited on the mask 92. Ultraviolet light passing through the transparent portion(s) of the mask 92 may cause a reaction in the photosensitive material 90.

The system 10 further comprises a vessel 20 for containing a liquid refractive index medium 22. The vessel 20 has a top portion 24. The top portion 24 may have an opening 26. One or more flexible sides 28 extend from the top portion 24. A base 30 abuts the flexible side(s) 28 and is in sealing relation with the flexible side(s) 28. The flexible side(s) 28 may be configured about the opening 26, such that the base 30, the flexible side(s) 28 and the top portion 24 form a container in which liquid refractive index medium 22 may be contained. The flexible side(s) 28 may be configured such that a cross-section of the vessel 20, taken perpendicular to a longitudinal axis L, may be circular, elliptical, rectilinear, or any other configuration.

The base 30 is selected from transparent materials such as, for example, glass or acrylic. The base 30 has a flat portion 32 configured to be placed adjacent to the mask 92. In this way, the flat portion 32 of the base 30 may be substantially parallel to the mask 92. In use, ultraviolet light may pass through the transparent base 30 and the transparent portion of the mask 92 to expose the photosensitive material 90. An interface medium 34 may be deposited on a bottom surface 36 of the base 30. The interface medium 34 may be, for example, elastomeric polydimethylsiloxane (PDMS). The interface medium 34, if any, improves the interface between the base 30 and the mask 92. In this way, the chances of air being trapped in the base-mask interface is decreased.

The flexible side(s) 28 allow the base 30 to move relative to the top portion 24 (see, e.g., FIG. 1B). In this manner, a liquid refractive index medium 22 contained in the vessel 20 will remain contained during any movement of the base 30. The base 30 may move in conjunction with the mask 92 and the stage 12.

It should be noted that the photosensitive material 90 and the mask 92 form no part of the present invention. Rather the photosensitive material 90 and mask 92 are interchangeable workpieces (or consumable environmental elements), which are used in conjunction with the present invention.

The system 10 may further comprise a supporter 40 between the stage 12 and a mask 92. The supporter 40 may prevent the weight of the vessel 20 from damaging the photosensitive material 90.

The system 10 may further comprise a liquid refractive index medium 22 contained in the vessel 20. The liquid refractive index medium 22 may be selected from a material having a refractive index greater that one. The liquid refractive index medium 22 may be selected from a material having a refractive index between 1 and 2. A transparent plate 38 may be contained within the vessel 20. The transparent plate 38 may be disposed on a top surface of the liquid refractive index medium 22. In this manner, the transparent plate 38 may decrease any disruption of the top surface of the liquid refractive index medium 22 when the base 30 is in motion.

The invention may be embodied as a vessel 20 as described above, without a stage 12.

In use, ultraviolet light may be caused to pass through the vessel 20, including the top portion 24, any liquid refractive index medium 22 and the base 30. The ultraviolet light may then pass through any transparent portions of a mask 92 and cause the photosensitive material 90 to react. For example, when SU-8 is used as a photosensitive material, ultraviolet light may cause the SU-8 to polymerize. The stage 12 may be moved before or during exposure of the photosensitive material 90.

Thus, the invention may be embodied as a method 100 for multidirectional ultraviolet lithography. In such a method 100, a movable stage is provided 110. A photosensitive material is provided 120 on a top surface of the movable stage. A mask may be provided 130 and disposed on the photosensitive material. As previously stated, the mask may have transparent portion(s) and opaque portion(s). A vessel is provided 140 and placed on the mask. The vessel may be of the type described herein having a top portion and a base, which may move relative to the top portion. The base of the vessel is configured with a flat portion which is disposed on the mask. The vessel may contain a liquid refractive index medium. An ultraviolet light source is used 150 to pass ultraviolet light through the vessel and the mask (if present) to cause the photosensitive material to react. The photosensitive material may be exposed to the ultraviolet light for a predetermined period of time. The stage may be caused to move 160 before and/or during the predetermined period of time.

The present disclosure uses a liquid-state refractive index matching medium to overcome a limit of the inclined angle for the three-dimensional (“3D”) microstructures fabricated by conventional dynamic mode multidirectional ultraviolet (“UV”) lithography (“DMUL”). The disclosed approach uses a vessel to isolate a liquid refractive index medium such that there is no direct contact between the liquid refractive index medium and the photosensitive material, reducing the chance of contamination, simplifying the fabrication process, and broadening the selection of the appropriate liquid refractive index medium. In addition, the liquid vessel is designed to allow in-situ adjustable refractive index matching performance during a dynamic mode operation. In a non-limiting example, a refracted angle of 58.5° for an incident angle of 67.5° has been obtained for an SU-8 structure using glycerol as an index matching medium. UV lithography using water, solvent, acid, oil, and starch syrup as an index matching medium has been demonstrated. Various microstructures with large inclined or flare angles such as a chevron shape, an ellipsoidal horn, and a chained wind vane are successfully demonstrated with dynamic mode multidirectional UV lithography.

The purpose of DMUL is to fabricate complex 3D microstructures using a movable stage with a motor controller to effect stage tilting and/or rotation, and a collimated UV light source. Advantages of this configuration are the creation of inclined structures from tilting the stage; horn or wave type structures from rotating the stage; and/or unusual 3D microstructures with nonaxisymmetric curved sidewalls from simultaneously tilting and rotating the stage.

An adjustable refractive index method is demonstrated using liquids of various refractive indices in a separate vessel, by which the fabrication process is simplified by not needing to submerge the system into liquid. A separate vessel also allows for a wider variety of liquid refractive index medium materials. The container for refractive index materials is designed to be flexible to accommodate dynamic mode stage movement while preserving index matching performance. Also, UV lithography experiments using various liquid refractive index medium materials are performed. Using the system disclosed herein, complex 3D microstructures having enlarged inclined or flare angles have been demonstrated such as a chevron shape pillar array, an ellipsoidal horn array, and a chained vane array.

To increase the achievable inclined angle of the tilted 3D microstructures from the multidirectional UV exposure scheme, a liquid refractive index medium is positioned between the light source surrounded by air and the photosensitive material. A commonly used photoresist such as SU-8 (having a high refractive index of 1.69) may be used, and a liquid refractive index medium is selected to closely match refractive index of the photosensitive material.

Moreover, for the dynamic mode multidirectional exposure scheme using a fixed collimated light source and a movable stage holding a polymer substrate and photomask, adjustment of the geometry of the liquid refractive index medium is necessary. The interface between air and the liquid refractive index medium should be substantially perpendicular to the incident light, while the tilting angle of the interface between the liquid refractive index medium (by way of the base of the vessel) and the photoresist may vary. To satisfy these requirements, the use of a deformable vessel to contain the liquid refractive index medium is disclosed.

A fully computer controlled dynamic mode multidirectional UV exposure scheme may be used, wherein the stage is independently controlled for tilting and rotating during UV exposure as programmed by a user. This technique includes not only all advantages of conventional UV lithography but also complex 3D patterning for UV lithography.

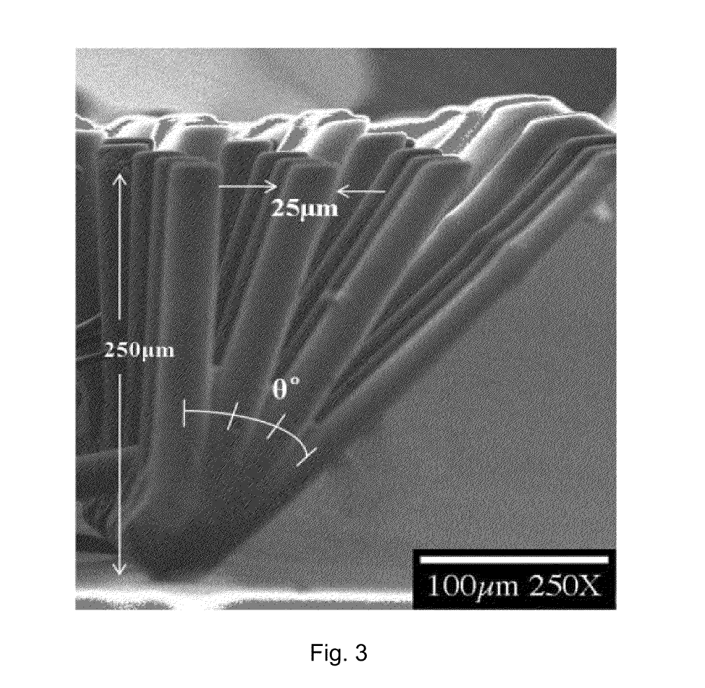

Multiple exposures with different incident angles through the clear window photomask have been performed using various refractive index media. A fabricated SU-8 structure from an open window with a diameter of 25 μm and a thickness of 250 μm is shown in FIG. 3.

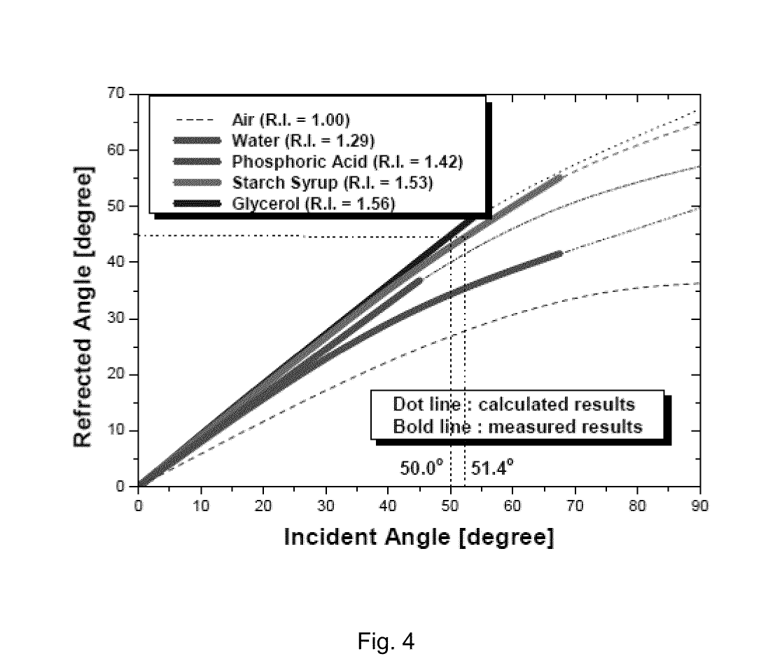

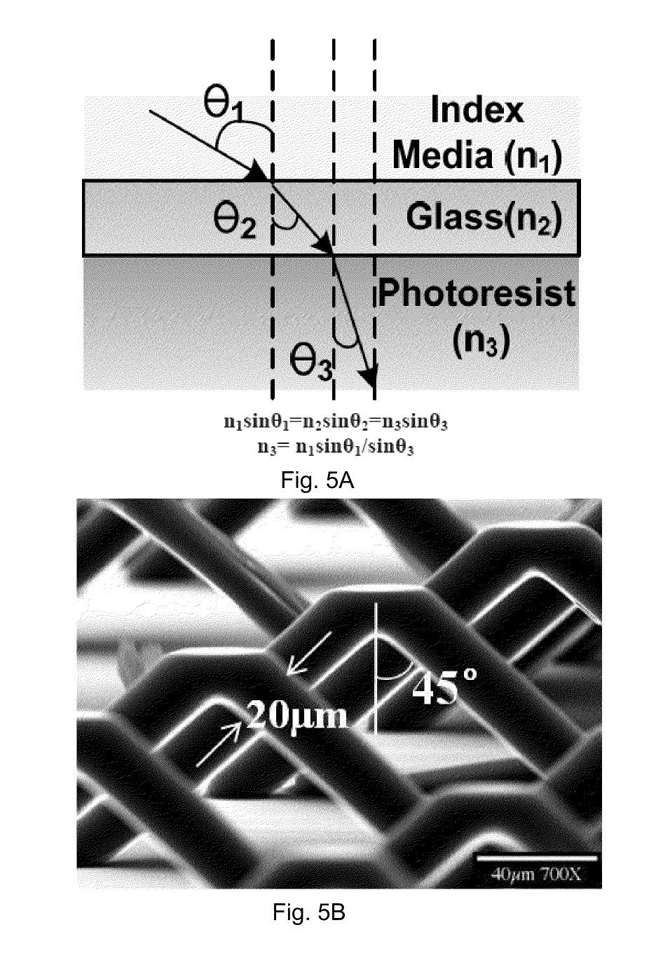

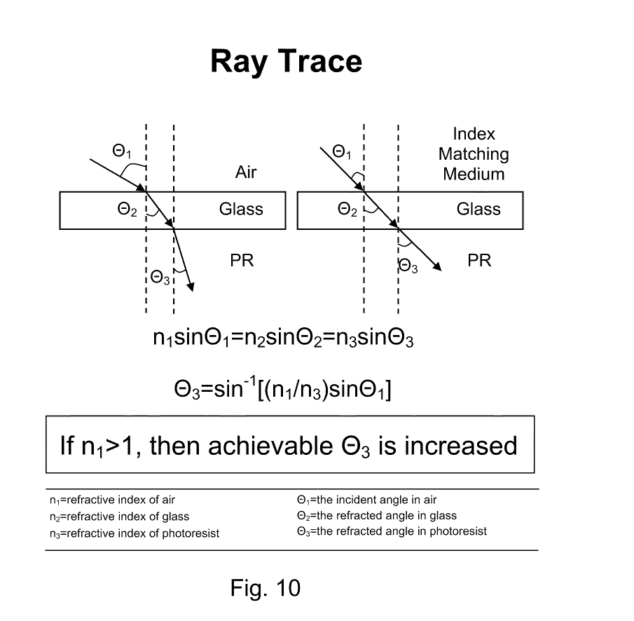

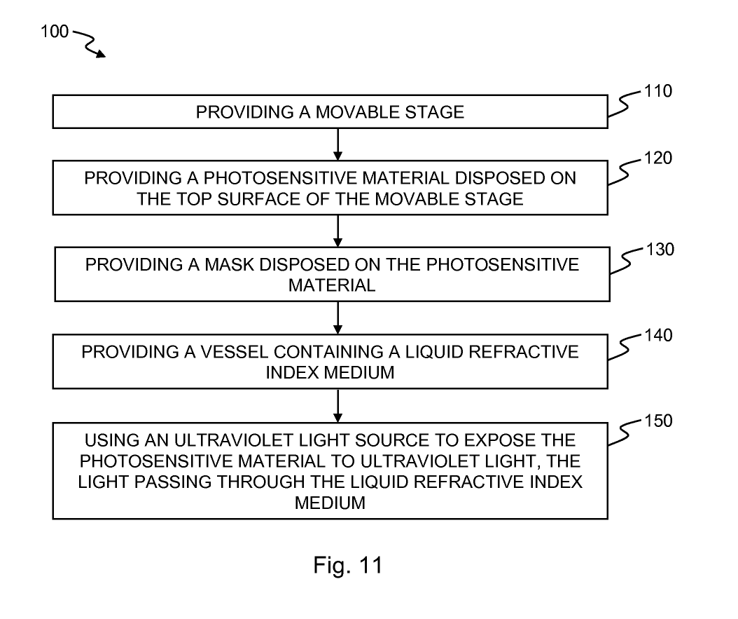

Various incident angles and refracted angles for water, phosphoric acid, starch syrup, and glycerol media have been measured for SU-8 structures. The refractive indices of the materials are experimentally determined for the light source (LS 30, OAI Inc.). Glycerol shows the largest achievable refracted angle among those tested with a refractive index of 1.56 (shown in FIG. 4). While a refracted angle of 45°, which is an important angle for many optical applications such as a prism or a mirror, may not be achieved with an air environment multidirectional scheme, the angle has been obtained with an incident angle of 50° and 51.4° for an index matching medium of glycerol and starch syrup, respectively. Other refracted angles for incident angles of 0°, 22.5°, 45°, and 67.5° are summarized in Table 1 (below), where the refractive index is calculated using measured angles and Snell's law as shown in FIGS. 5A and 10, where n1, n2, and n3 are the refractive indices of air, glass, and photoresist, respectively, and θ1, θ2, and θ3 are the incident angle, the refracted angle in glass, and the refracted angle in photoresist, respectively.

TABLE 1

| Incident | | | | | Nitric | Phosphoric | Starch | |
|---|---|---|---|---|---|---|---|---|
| Angle | Water | IPA | Acetone | Methanol | Acid | Acid | Syrup | Glycerol |
| 22.5 | 18.09 | 17.78 | 18.43 | 20.40 | 18.00 | 18.44 | 20.22 | 20.82 |
| 45 | 32.85 | 34.70 | 36.00 | 40.19 | 34.21 | 36.74 | 39.72 | 40.12 |
| 67.5 | 44.00 | — | — | — | — | — | — | 58.52 |
| Refractive | 1.29 | 1.36 | 1.39 | 1.54 | 1.36 | 1.42 | 1.53 | 1.56 |
| Index | | | | | | | | |

Since the refractive indices of glycerol and starch syrup are relatively closer to that of the SU-8 than other tested liquids, these materials were utilized as liquid refractive index media in the fabrication of structures with a tilting angle of 45° or greater.

FIG. 5B shows an inclined pillar array with a refracted angle of 45° from bottom exposure. The top surface has been interfaced with a reflecting surface and the reflected pillar and the incident pillar form a chevron shape array with an angle of 90° between two branches.

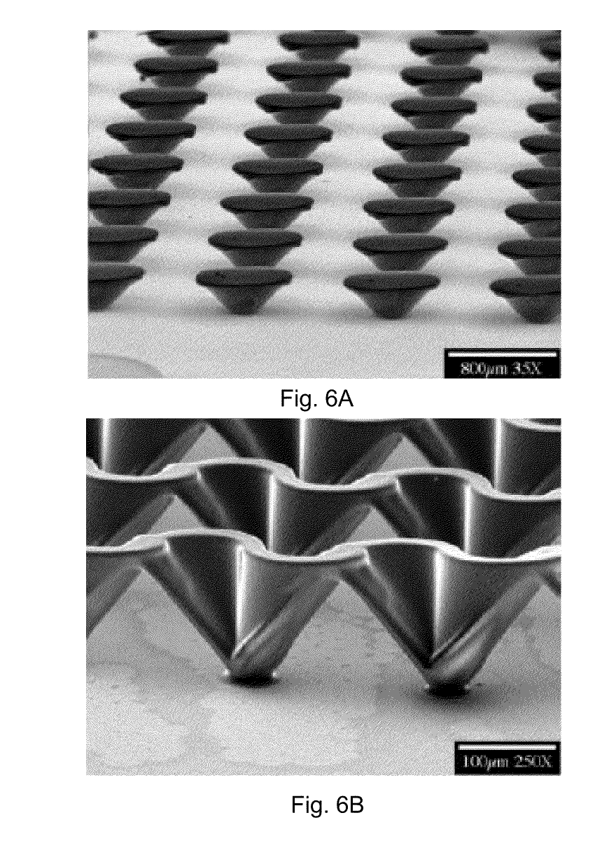

FIG. 6A shows an array of ellipsoidal horns fabricated using a dynamic mode operation, where a flare angle of 90° is successfully implemented. In FIG. 6B, another dynamic mode operation with glycerol as a matching medium shows a chained wind vane with a flare angle of 85° compared to the isolated wind vane performed in an air environment with a flare angle of 45°.

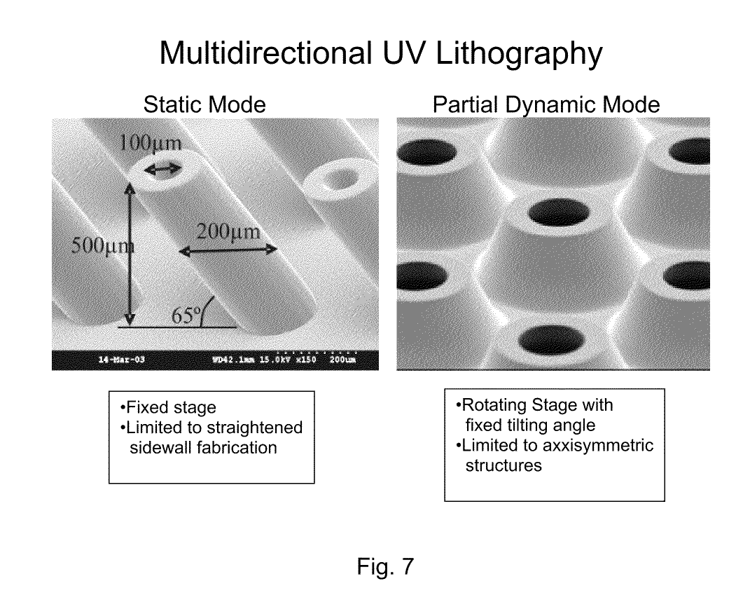

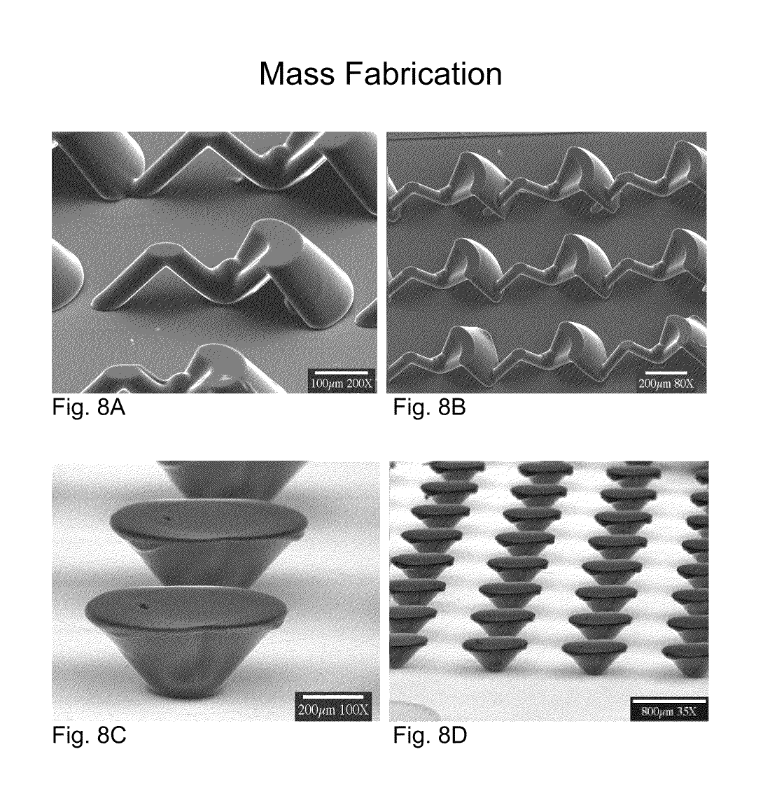

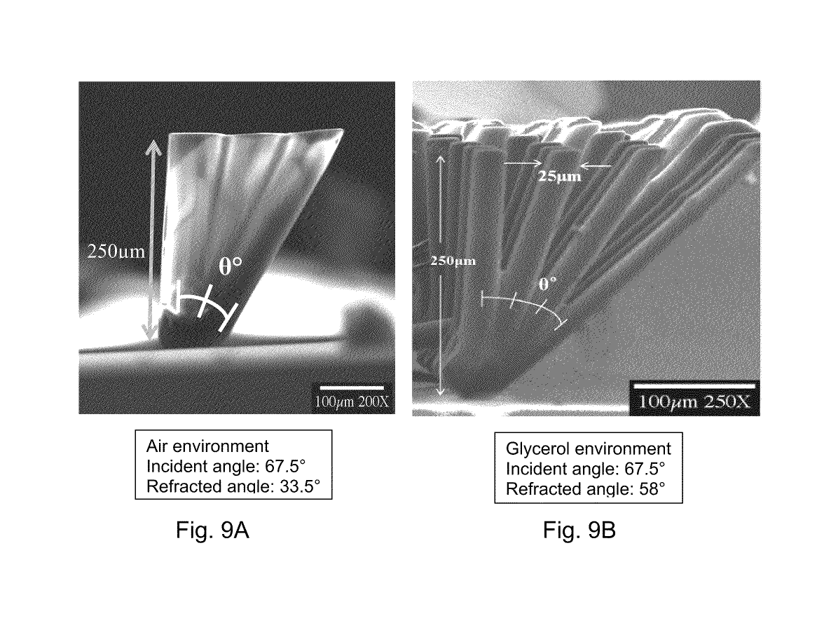

With the expanded refracted angle capability, more complex 3D micro-structures are available in dynamic mode multidirectional UV lithography (see, e.g., FIGS. 7 and 8A-8D), which can find useful applications in optics, RF, and bio fields. Some structures that can be made with the disclosed method and apparatus/system are vertically standing micro antennae, 3D micro waveguides, 3D scaffolds for cell culture and implantation, and 3D micro mixers. While previous techniques and systems require alignment and several exposure steps to make a complex 3-D micro structure, the disclosed apparatus and method offer efficient fabrication of complex 3D structures in a single exposure.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. A vessel for containing a liquid refractive index medium, comprising:
a top portion having an opening;
one or more flexible sides extending from the top portion;
a transparent base abutting and in sealing relation with the one or more flexible sides, the base having a flat portion configured to be placed adjacent to a mask; and
wherein the base is movable relative to the top portion.

2. The vessel of claim 1, further comprising a transparent plate contained in the vessel.

3. The vessel of claim 1, further comprising an interface medium disposed on a bottom surface of the base.

4. The vessel of claim 1, further comprising a liquid refractive index medium contained in the vessel.

5. The vessel of claim 4, further comprising a transparent plate disposed on a top surface of the liquid refractive medium.

6. The vessel of claim 4, wherein the liquid refractive index medium has a refraction index greater than 1.

7. The vessel of claim 6, wherein the liquid refractive index medium has a refraction index between 1 and 2.

8. A system for multidirectional ultraviolet lithography, comprising:
a stage having a top surface for receiving a photosensitive material and a mask;
a vessel for containing a liquid refractive index medium, comprising:
a top portion having an opening;
one or more flexible sides extending from the top portion; and
a transparent base abutting and in sealing relation with the one or more flexible sides, the base having a flat portion configured to be placed adjacent to the mask; and
wherein the base and the stage are movable relative to the top portion of the vessel.

9. The system of claim 8, further comprising a supporter disposed on the top surface of the stage.

10. A method for multidirectional ultraviolet lithography, comprising the steps of:
providing a movable stage;
providing a photosensitive material disposed on the top surface of the movable stage;
providing a mask disposed on the photosensitive material;
providing a vessel containing a liquid refractive index medium, the vessel having a base and a top portion, wherein the base is disposed on the mask, and wherein the base is movable relative to top portion; and
using an ultraviolet light source to expose the photosensitive material to ultraviolet light for a predetermined period of time, the ultraviolet light passing through the liquid refractive index medium.

11. The method of claim 10, further comprising the step of providing a mask between the photosensitive material and the base of the vessel.

12. The method of claim 11, further comprising the step of moving the movable stage during the predetermined period of time.
